(19) United States
(12) Patent Application Publication
(10) Pub. No.: US 2013/0101140 A1
(43) Pub. Date: Apr. 25, 2013

(54) ELECTRONIC DEVICE AND METHOD OF OPERATING THE SAME

(71) Applicants: Eunhyung CHO, Seoul (KR); Yongsin KIM, Seoul (KR)

(72) Inventors: Eunhyung CHO, Seoul (KR); Yongsin KIM, Seoul (KR)

(73) Assignee: LG ELECTRONICS INC., Seoul (KR)

(21) Appl. No.: 13/280,413

(22) Filed: Oct. 25, 2011

(51) Int. Cl. H03G 3/02; G09G 5/00

(52) U.S. Cl. 381/109; 345/204

(57) ABSTRACT

An electronic device and a method of operating the same are provided. By providing an electronic device and a method of operating the electronic device for easily changing a sound output mode when performing communication, user convenience is provided.

### FIELD OF THE INVENTION

The present invention relates to an electronic device and a method of operating the same, and more particularly, to an electronic device and a method of operating the same that can easily change a sound output mode when performing communication.

### DISCUSSION OF THE RELATED ART

As electronic devices (terminals) such as a personal computer (PC), a laptop computer, and a mobile phone have various functions, the electronic devices are embodied as a multimedia player having complex functions such as photographing of a picture or a moving picture, reproduction of a music file or a moving picture file, playing of a game, and reception of broadcasting.

The electronic devices are classified into a mobile terminal and a stationary terminal according to mobility. The mobile terminals are classified into a handheld terminal and a vehicle mount terminal according to a user's portability.

In order to support and enlarge a function of the electronic device, it is considered to improve a structural portion and/or a software portion of the electronic device.

### SUMMARY

An aspect of the present invention is to provide an electronic device and a method of operating the same that can change a communication sound output mode while displaying an application requested while performing communication.

Another aspect of the present invention is to provide an electronic device and a method of operating the same that can provide together an application execution screen executed before starting communication and an application execution screen executed after starting communication.

Another aspect of the present invention is to provide an electronic device and a method of operating the same that can control a communication voice output mode through a volume adjustment button while performing communication according to a preset communication sound output mode.

The object of the present invention is not limited to the above-described objects and the other objects will be understood by those skilled in the art from the following description.

In an aspect, an electronic device includes: a display; an audio output unit; and a controller for acquiring, when a request for execution of a first application is received while outputting communication sound in a preset sound output mode through the audio output unit, a control signal for controlling the preset sound output mode in a state of displaying an execution screen of the requested first application in the display.

In another aspect, an electronic device includes: a display; and a controller for providing an application execution screen together with a guide screen related to communication when starting the communication while outputting the application execution screen through the display.

In another aspect, an electronic device includes: a communication sound adjustment button; and a controller for acquiring a control signal for controlling a preset communication sound output mode through the communication sound adjustment button while performing communication based on the preset communication sound output mode.

In another aspect, a method of operating an electronic device, the method includes: outputting communication sound in a preset sound output mode as communication starts; receiving a request for execution of a first application while performing communication; and acquiring a control signal for controlling the preset sound output mode in a state of displaying an execution screen of the first application according to the request for execution of the first application.

According to an electronic device and a method of operating the same according to the present invention, by changing a communication voice output mode while displaying an application requested while performing communication, an easy and convenient operating environment is provided.

According to an electronic device and a method of operating the same according to the present invention, by continuing to output together an application execution screen executed before starting communication and an application execution screen executed after starting communication, an environment that can manipulate a user interface even while performing communication is provided.

According to an electronic device and a method of operating the same according to the present invention, while performing communication according to a preset communication voice output mode, by controlling a communication voice output mode through a volume adjustment button, a more convenient operating environment is provided.

### BRIEF DESCRIPTION OF THE DRAWINGS

The accompany drawings, which are included to provide a further understanding of the present invention and are incorporated on and constitute a part of this specification illustrate embodiments of the present invention and together with the description serve to explain the principles of the present invention.

FIG. 1 is a block diagram illustrating a configuration of an electronic device according to an exemplary embodiment of the present invention;

FIG. 2 is a flowchart illustrating a method of operating an electronic device according to a first exemplary embodiment of the present invention;

FIG. 3 is a diagram illustrating a sound output mode according to a first exemplary embodiment of the present invention;

FIG. 4 is a diagram illustrating execution of an application while performing communication according to a first exemplary embodiment of the present invention;

FIG. 5 is a table illustrating a sound output mode change reference according to a first exemplary embodiment of the present invention;

FIG. 6 is a diagram illustrating an example of a method of acquiring a control signal according to a first exemplary embodiment of the present invention;

FIG. 7 is a diagram illustrating another example of a method of acquiring a control signal according to a first exemplary embodiment of the present invention;

FIGS. 8 and 9 are diagrams illustrating another example of a method of acquiring a control signal according to a first exemplary embodiment of the present invention;

FIG. 10 is a diagram illustrating another example of a method of acquiring a control signal according to a first exemplary embodiment of the present invention;

FIG. 11 is a diagram illustrating another example of a method of acquiring a control signal according to a first exemplary embodiment of the present invention;

FIG. 12 is a diagram illustrating an application example of a method of operating an electronic device according to a first exemplary embodiment of the present invention;

FIG. 13 is a flowchart illustrating a method of operating an electronic device according to a second exemplary embodiment of the present invention;

FIG. 14 is a diagram illustrating an interface for controlling a television according to a second exemplary embodiment of the present invention;

FIG. 15 is a diagram illustrating a manipulation interface output on a communication related guide screen according to a second exemplary embodiment of the present invention;

FIG. 16 is a diagram illustrating an interface according to a second exemplary embodiment of the present invention;

FIG. 17 is a flowchart illustrating a method of operating an electronic device according to a third exemplary embodiment of the present invention;

FIG. 18 is a table illustrating a volume adjustment button input and a sound output mode corresponding thereto according to a third exemplary embodiment of the present invention; and

FIGS. 19 and 20 are diagrams illustrating a use state of step S340 according to a third exemplary embodiment of the present invention.

### DETAILED DESCRIPTION

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description. Like reference numerals designate like elements throughout the specification. Further, detailed descriptions of well-known functions and structures incorporated herein may be omitted to avoid obscuring the subject matter of the present invention. Further, numerals (e.g., first and second) used when describing the present invention are identity symbols for distinguishing one constituent element from another constituent element.

Hereinafter, an electronic device according to the present invention will be described in detail with reference to the drawings.

In the following description, suffixes “module” and “unit” of constituent elements are given or used for easily describing a specification, instead of having a distinctive meaning or function.

An electronic device described in this document may include a mobile phone, a smart phone, a laptop computer, a digital broadcasting terminal, a personal digital assistant (PDA), a portable multimedia player (PMP), and a navigation device. However, a configuration according to exemplary embodiments described in this document can be applied even to a fixed terminal such as a digital television and a desktop computer, except for a configuration that can be applied only to an electronic device and this will be easily understood by those skilled in the art.

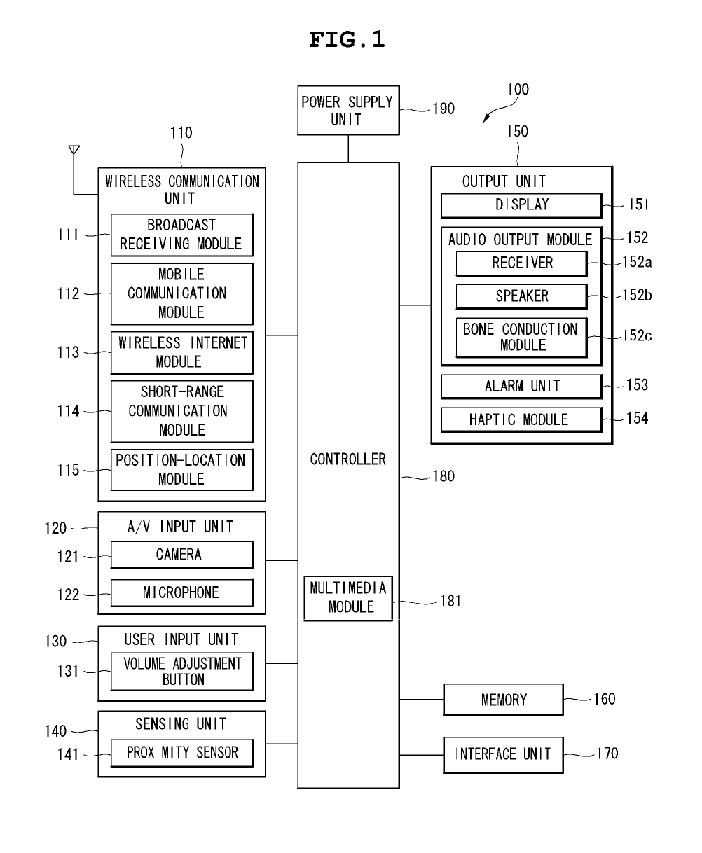

FIG. 1 is a block diagram illustrating a configuration of an electronic device 100 according to an exemplary embodiment of the present invention.

The electronic device 100 includes a wireless communication unit 110, an audio/video (A/V) input unit 120, a user input unit 130, a sensing unit 140, an output unit 150, a memory 160, an interface unit 170, a controller 180, and a power supply unit 190. Because constituent elements shown in FIG. 1 are not essential, the electronic device 100 may include constituent elements more than or less than those shown in FIG. 1.

Hereinafter, the constituent elements are described in detail.

The wireless communication unit 110 includes at least one module for allowing wireless communication between the electronic device 100 and a wireless communication system, or between the electronic device 100 and a network at which the electronic device 100 is positioned. For example, the wireless communication unit 110 may include at least one of a broadcasting reception module 111, a mobile communication module 112, a wireless Internet module 113, a short range communication module 114, and a position information module 115.

The broadcasting reception module 111 receives a broadcasting signal and/or broadcasting related information from an external broadcasting management server through a broadcasting channel.

The broadcasting channel includes a satellite channel and a terrestrial channel. The broadcasting management server may be a server for generating and transmitting a broadcasting signal and/or broadcasting related information, or a server for receiving the generated broadcasting signal and/or broadcasting related information and for transmitting the received broadcasting signal and/or broadcasting related information to the terminal. The broadcasting signal may include a television broadcasting signal, a radio broadcasting signal, a data broadcasting signal, and a broadcasting signal in which the data broadcasting signal is coupled to the television broadcasting signal or the radio broadcasting signal.

The broadcasting related information may be information related to a broadcasting channel, a broadcasting program, or a broadcasting service provider. The broadcasting related information may be provided through a mobile communication network. In this case, the broadcasting related information may be received by the mobile communication module 112.

The broadcasting related information may exist in various forms. For example, the broadcasting related information may exist in a form of an electronic program guide (EPG) of digital multimedia broadcasting (DMB), or an electronic service guide (ESG) of digital video broadcast-handheld (DVB-H).

The broadcasting reception module 111 receives a broadcasting signal using various broadcasting systems and particularly, may receive a digital broadcasting signal using a digital broadcasting system such as digital multimedia broadcasting-terrestrial (DMB-T), digital multimedia broadcasting-satellite (DMB-S), media forward link only (MediaFLO), digital video broadcast-handheld (DVB-H), and integrated services digital broadcast-terrestrial (ISDB-T). Further, the broadcasting reception module 111 may be formed to be appropriate to other broadcasting systems for providing a broadcasting signal as well as the above-described digital broadcasting system.

The broadcasting signal and/or the broadcasting related information received through the broadcasting reception module 111 may be stored in the memory 160. The mobile communication module 112 transmits and receives a wireless signal with at least one of a base station, an external terminal, and a server in a mobile communication network. The wireless signal may include various forms of data according to transmission and reception of an audio-dedicated call signal, an audiovisual communication call signal, or a text/multimedia message.

The wireless Internet module 113 is a module for connecting to wireless Internet and may be provided at the inside or the outside of the electronic device 100. As wireless Internet technology, wireless LAN (WLAN) (Wi-Fi), wireless broadband (Wibro), world interoperability for microwave access (Wimax), and high speed downlink packet access (HSDPA) may be used.

The short range communication module 114 is a module for short range communication. As short range communication technology, Bluetooth, radio frequency identification (RFID), infrared data association (IrDA), ultra wideband (UWB), and ZigBee may be used.

The position information module 115 is a module for checking or obtaining a position of an electronic device. A typical position information module is a global position system (GPS) module. According to present technology, the GPS module 115 calculates three-dimensional (3D) position information according to a latitude, a longitude, and an altitude of one point (object) at one time point by calculating information about a distance in which one point (object) is separated from three or more satellites and information about a measured time point of the distance information and then applying trigonometry to the calculated distance information. Further, a method of calculating position and time information using three satellites and adjusting an error of the calculated position and time information using another satellite is used. The GPS module 115 continues to calculate a present position in real time and calculates speed information using the calculated positions.

Referring to FIG. 1, the A/V input unit 120 is used for inputting an audio signal or a video signal and includes a camera 121 and a microphone 122. The camera 121 processes an image frame of a still image or a moving image obtained by an image sensor in an audiovisual communication mode or a photographing mode. The processed image frame is displayed in the display 151.

The image frame processed in the camera 121 may be stored in the memory 160, or transmitted to the outside through the wireless communication unit 110. According to a configuration of the electronic device 100, two or more cameras 121 may be provided.

The microphone 122 receives an input of an external sound signal and processes the external sound signal to electrical sound data in a communication mode, a recording mode, or a voice recognition mode. The processed sound data are converted to a form that can be transmitted and are output to a mobile communication base station through the mobile communication module 112 in a communication mode. The microphone 122 executes various noise removal algorithms for removing noise generated when receiving an input of an external sound signal.

The user input unit 130 is used for inputting data for controlling an operation of the electronic device 100 by a user. The user input unit 130 includes a keypad, a dome switch, a touch pad (static pressure/static electricity), a jog wheel, and a jog switch.

Further, the user input unit 130 further includes a volume adjustment button 131.

The volume adjustment button 131 controls sound output intensity of the audio output module 152 to be described later. For example, the volume adjustment button 131 may control an intensity level of communication sound and an intensity level of various notification sounds. For this, the volume adjustment button 131 includes a volume up button and a volume down button. Further, the volume adjustment button 131 is referred to as a communication sound adjustment button, as needed.

The sensing unit 140 detects a present state of the electronic device 100 such as an opening or closing state of the electronic device 100, a position of the electronic device 100, a user contact, an orientation of the electronic device 100, and acceleration/deceleration of the electronic device 100 and generates a sensing signal for controlling an operation of the electronic device 100. For example, when the electronic device 100 has a slide phone form, the sensing unit 140 detects an opening or closing state of a slide phone. Further, the sensing unit 140 may perform a sensing function related to power supply of the power supply unit 190 and coupling of the interface unit 170 to external appliances.

Further, the sensing unit 140 may include a proximity sensor 141.

The proximity sensor 141 is a sensor for detecting an object approaching a predetermined detection surface, or an object existing at a periphery thereof using an electromagnetic field force or infrared ray without a mechanical contact. When a subject is positioned within a predetermined distance, the proximity sensor 141 generates a predetermined control signal. The controller 180 recognizes that a subject is positioned within a predetermined distance according to a control signal from the proximity sensor 141 and performs a corresponding control operation.

The proximity sensor 141 may include, for example, a transmissive photoelectric sensor, a direct reflective photoelectric sensor, a mirror reflective photoelectric sensor, a high frequency oscillation proximity sensor, a capacitive proximity sensor, a magnetic proximity sensor, and an infrared ray proximity sensor.

The output unit 150 generates the output related to visual sense, auditory sense, or tactile sense and includes a display 151, an audio output module 152, an alarm unit 153, and a haptic module 154.

The display 151 displays information processed in the electronic device 100. For example, when the electronic device 100 is in a communication mode, the display 151 displays a user interface (UI) or a graphic user interface (GUI) related to communication. When the electronic device 100 is in an audiovisual communication mode or a photographing mode, the electronic device 100 displays a photographed or/and received image, an UI, and a GUI.

The display 151 includes at least one of a liquid crystal display (LCD), a thin film transistor-liquid crystal display (TFT-LCD), an organic light-emitting diode, a flexible display, and a 3D display.

In order to view the outside through the display, some display may be formed in a transparent type or a light transmitting type. This is referred to as a transparent display, and a typical transparent display is a transparent LCD. A rear structure of the display 151 may be also formed in a light transmitting type structure. Due to such a structure, the user can view an object positioned at the rear side of a terminal body through an occupying area of the display 151 of the terminal body.

According to an implementation form of the electronic device 100, two or more displays 151 may exist. For example, in the electronic device 100, a plurality of displays may be disposed apart at one surface, be integrally disposed, or be each disposed at different surfaces.

When the display 151 and a sensor (hereinafter, referred to as a ‘touch sensor’) for detecting a touch action are formed in an interlayer structure (hereinafter, referred to as a ‘touch screen’), the display 151 can be used as an input device as well as an output device. The touch sensor may have a form such as a touch film, a touch sheet, and a touch pad.

The touch sensor can convert the change of a pressure applied to a specific portion of the display 151, or the change of capacitance occurred in a specific portion of the display 151 to an electrical input signal. The touch sensor can detect a touched position, a touched area, and a touched pressure.

When a touch is input to the touch sensor, a signal corresponding thereto is transferred to a touch controller. The touch controller processes the signal and transfers corresponding data to the controller 180. Thereby, the controller 180 can know a touch area of the display 151.

A capacitive touch screen detects the approach of the pointer with the change of an electric field according to the approach of a pointer on the touch screen. In this case, the touch screen (touch sensor) may be classified into a proximity sensor.

Hereinafter, for convenience of description, an action of recognizing that a pointer is positioned on the touch screen as the pointer approaches without touching on the touch screen is referred to as a “proximity touch”, and an action in which a pointer is actually touched on the touch screen is referred to as a “contact touch”. A position at which a pointer performs a proximity touch on the touch screen is a position vertically corresponding to the touch screen when the pointer performs a proximity touch.

The audio output module 152 may output audio data received from the wireless communication unit 110, or stored in the memory 160 in a call signal reception mode, a communication mode or a recording mode, a voice recognition mode, and a broadcasting reception mode. The audio output module 152 outputs a sound signal related to a function (e.g., call signal reception sound and message reception sound) performed in the electronic device 100.

The audio output module 152 may include at least one of a receiver 152a, a speaker 152b, and a bone conduction module 152c.

The alarm unit 153 outputs a signal notifying occurrence of an event in the electronic device 100. An event occurred in the electronic device 100 includes, for example, call signal reception, message reception, key signal input, and touch input. The alarm unit 153 may output a signal notifying occurrence of an event with a vibration in addition to a video signal or an audio signal. The video signal or the audio signal may be output through the display 151 or the audio output module 152.

The haptic module 154 generates various haptic effects in which a user can feel. A typical haptic effect generated by the haptic module 154 is a vibration. Intensity and a pattern of a vibration generated by the haptic module 154 can be adjusted. For example, the haptic module 154 may synthesize and output different vibrations, or sequentially output different vibrations.

The haptic module 154 may generate various haptic effects such as a stimulation effect due to arrangement of pins vertically moving relative to a skin contact surface, a stimulation effect using an injection force or an inhalation force of air through an injection nozzle or an inhalation nozzle, a stimulation effect due to grazing of a skin surface, a stimulation effect through a contact of an electrode, a stimulation effect using an electrostatic force, and a stimulation effect due to reproduction of cold and warmth feeling using an element that can absorb or emit heat, in addition to a vibration.

The haptic module 154 transfers a haptic effect through a direct contact and may be formed to feel a haptic effect through muscular sense of a user's finger or arm. According to a configuration of the electronic device 100, two or more haptic modules 154 may be provided.

The memory 160 stores a program for operating the controller 180 and may temporarily store input/output data (e.g., a phonebook, a message, a still image, and a moving image). The memory 160 may store data about various patterns of vibration and sound to be output when touching the touch screen.

The memory 160 may include at least one of a flash memory type, a hard disk type, a multimedia card micro type, and a card type memory (e.g., secure digital (SD) memory or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. The electronic device 100 may perform an operation related to web storage for performing a storage function of the memory 160 in Internet.

The interface unit 170 functions as a passage for external appliances connected to the electronic device 100. The interface unit 170 receives data or power from external appliances to transfer the data or power to constituent elements within the electronic device 100, or transmits data within the electronic device 100 to external appliances. For example, the interface unit 170 may include a wired/wireless headset port, an external charger port, a wired/wireless data port, a memory card port, a port for connecting a device having an identity module, an audio input/output (I/O) port, a video I/O port, and an earphone port.

Identity modules are chips for storing various information for certifying use authority of the electronic device 100 and may include a user identity module (UIM), a subscriber identity module (SIM), and a universal subscriber identity module (USIM). A device (hereinafter, ‘identity device’) having an identity module may be manufactured in a smart card form. Therefore, the identity device can be connected to the electronic device 100 through the port.

When the electronic device 100 is connected to an external cradle, the interface unit 170 may become a passage for supplying power from the cradle to the electronic device 100, or become a passage for transferring various instruction signals input to the cradle by a user to the electronic device 100. Various instruction signals or power input from the cradle may be used as a signal for recognizing that the electronic device 100 is accurately mounted in the cradle.

The controller 180 controls general operations of the electronic device 100. For example, the controller 180 performs control and processing related to audio-dedicated communication, data communication, and audiovisual communication. The controller 180 may include a multimedia module 181 for reproducing multimedia. The multimedia module 181 may be provided within the controller 180 or may be provided separately from the controller 180.

The controller 180 can perform a pattern recognition processing that can recognize cursive input or drawing input performed on a touch screen as a text or an image, respectively.

The power supply unit 190 receives external power and internal power by control of the controller 180 and supplies power necessary for operation of constituent elements.

Various exemplary embodiments described herein can be embodied within a record medium that can be read with a computer or a device similar to the computer using software, hardware, or a combination thereof.

When exemplary embodiments of the present invention are performed using hardware, exemplary embodiments described herein can be performed using at least one of application specific integrated circuits (ASICs), digital signal processors (DSPs), digital signal processing devices (DSPDs), programmable logic devices (PLDs), field programmable gate arrays (FPGAs), processors, controllers, microcontrollers, microprocessors, and an electrical unit for performing a function. In some cases, such exemplary embodiments can be performed by the controller 180.

When exemplary embodiments of the present invention are performed using software, exemplary embodiments such as a procedure and a function can be performed together with a separate software module for enabling to perform at least one function or operation. A software code can be performed by a software application prepared with an appropriate programming language. Further, the software code is stored in the memory 160 and executed by the controller 180.

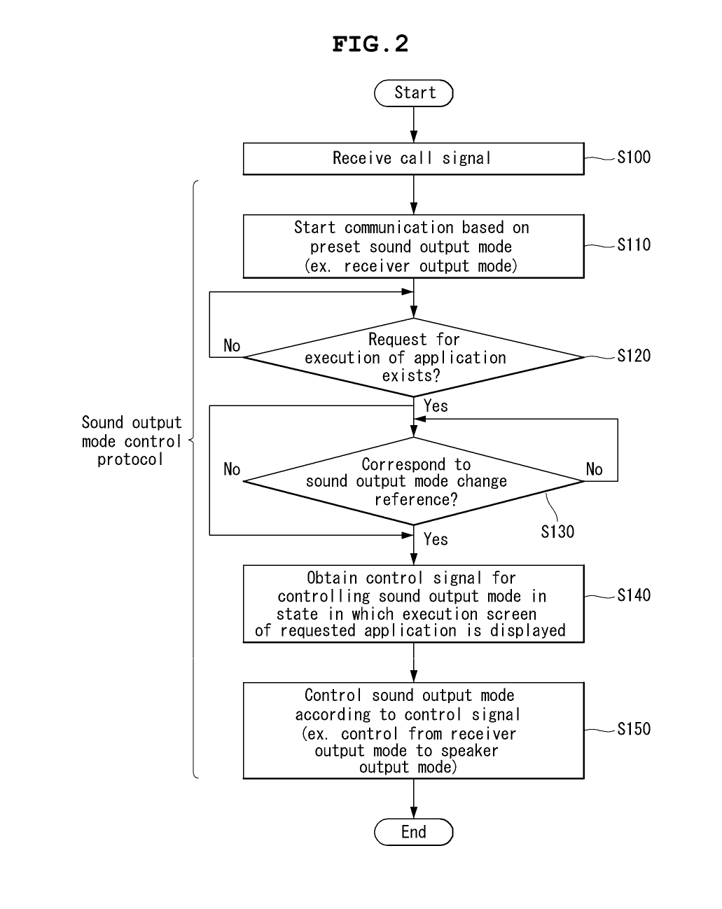

Hereinafter, a method of operating an electronic device according to a first exemplary embodiment of the present invention will be described with reference to FIG. 2.

FIG. 2 is a flowchart illustrating a method of operating an electronic device according to a first exemplary embodiment of the present invention.

In a method of operating an electronic device according to a first exemplary embodiment described with reference to FIG. 2, when a request for executing an application while performing communication exists, in a state where an execution screen of a requested application is displayed, a solution for changing a communication sound output mode is provided.

For this, a method of operating an electronic device according to a first exemplary embodiment of the present invention includes at least one of step of receiving a call signal (S100), step of starting communication based on a preset sound output mode (S110), step of determining whether a request for execution of an application exists (S120), step of determining whether corresponding to a sound output mode change reference (S130), step of acquiring a control signal for controlling a sound output mode in a state where an execution screen of a requested application is displayed (S140), and step of controlling a sound output mode according to a control signal (S150).

Particularly, at least one of step of determining whether a request for execution of an application exists (S120), step of determining whether corresponding to a sound output mode change reference (S130), step of acquiring a control signal for controlling a sound output mode in a state where an execution screen of a requested application is displayed (S140), and step of controlling a sound output mode according to a control signal (S150) is referred to as a sound output mode control protocol.

Hereinafter, each step will be described in detail. The electronic device 100 receives a call signal (S100).

The electronic device 100 transmits/receives various call signals, for example 3G (generation), Wibro, and a 4G signal such as long term evolution (LTE) according to mobile communication technology, and a signal according to a web phone that can perform communication with another party through Internet. The above-described call signal is one example, and the present invention is not limited to a specific call signal.

The electronic device 100 starts communication based on a preset communication sound output mode (S110).

The preset communication sound output mode includes various modes for outputting sound generated while the electronic device 100 performs communication. Hereinafter, the communication sound output mode is referred to as a sound output mode.

The communication sound output mode includes at least one of a receiver output mode and a speaker output mode.

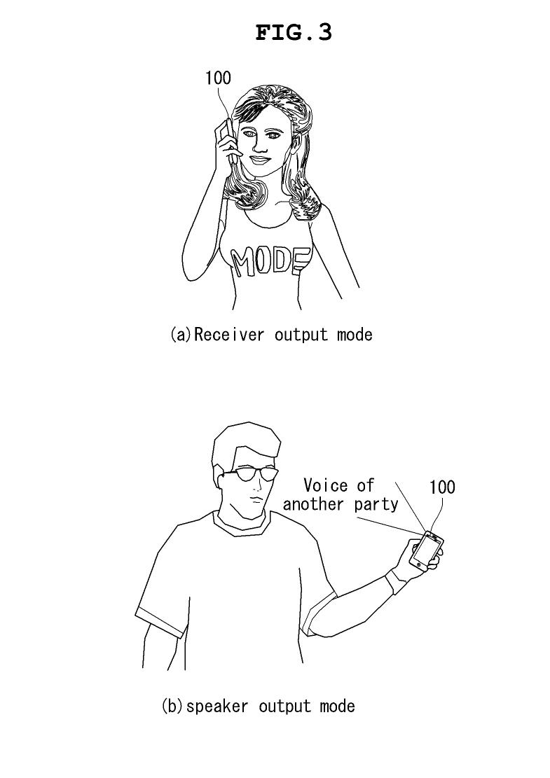

The sound output mode will be described in detail with reference to FIG. 3.

FIG. 3 is a diagram illustrating a sound output mode according to a first exemplary embodiment of the present invention.

Referring to FIG. 3A, the receiver output mode is a mode in which the electronic device 100 outputs sound through the receiver 152a. Particularly, the receiver output mode is a mode in which a user communicates by directly positioning the user's ear at the receiver 152a of the electronic device 100.

Referring to FIG. 3B, the speaker output mode is a mode in which the electronic device 100 outputs sound through the speaker 152b. Particularly, the speaker output mode is a mode in which the user can hear communication contents at a more long distance through the speaker 152b of the electronic device 100.

That is, the receiver output mode provides a communication environment closer than the speaker output mode.

Therefore, the user may perform proximity communication by selecting a receiver output mode according to a communication environment and perform communication through a speaker output mode.

Although not shown, the sound output mode may further include a bone conduction module output mode.

The bone conduction module output mode is a mode in which the electronic device 100 outputs sound through the bone conduction module 152c. The bone conduction module is a speaker having a bone conduction function. More specifically, the bone conduction module uses a principle in which a person can recognize and hear sound transferred with a vibration of bone and blood. That is, the bone conduction output module is a mode in which the user communicates by directly positioning the user's ear at the bone conduction module 152c of the electronic device 100.

Hereinafter, for convenience of description, it is assumed that a preset sound output mode at step S110 is a receiver output mode.

Referring again to FIG. 2, the electronic device 100 receives a request for execution of an application (S120).

The electronic device 100 receives a request for execution of an application by various methods while performing communication. For example, the electronic device 100 receives a request for execution of a specific application through the user's application execution manipulation, and as another example, the electronic device 100 receives a request for execution of an application through the user's voice instruction.

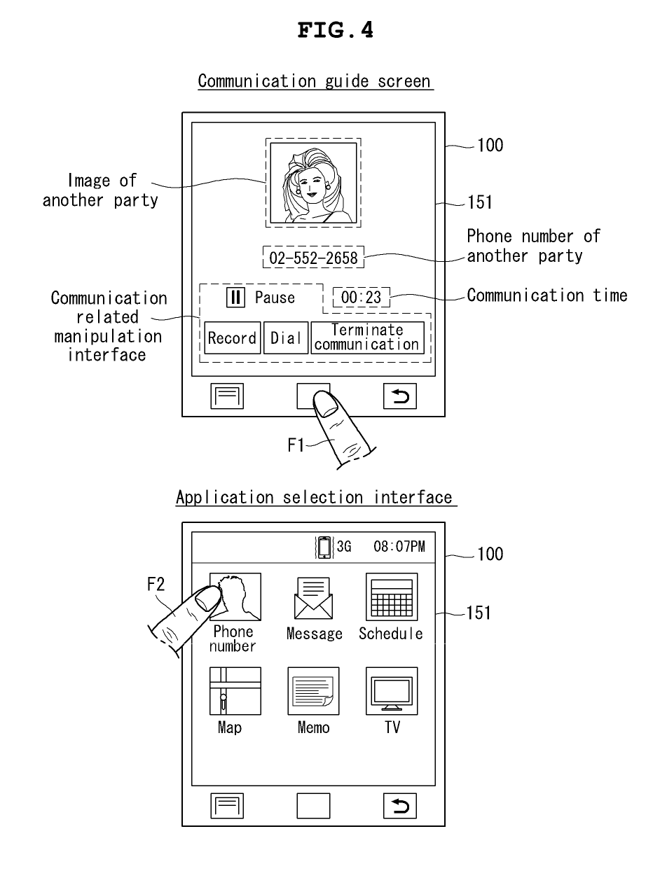

Step S120 will be described in detail with reference to FIG. 4.

FIG. 4 is a diagram illustrating execution of an application while performing communication according to a first exemplary embodiment of the present invention.

FIG. 4A is a diagram illustrating a communication guide screen according to a first exemplary embodiment of the present invention.

As shown in FIG. 4A the electronic device 100 provides a communication guide screen through the display 151. The communication guide screen can provide various information and manipulation interfaces related to presently performing communication. More specifically, the communication guide screen can provide an image and a phone number of another party, information and recording related to communication such as communication time, and a communication related manipulation interface such as a dial and communication termination.

The electronic device 100 outputs the communication guide screen when a user's request receives while performing communication in a receiver output mode. For example, when a proximity sensing signal does not exist in a receiver output mode, the electronic device 100 determines that the user's ear is separated from the electronic device 100 and outputs a communication guide screen according to the determination.

The user can request execution of an application in a state where the communication guide screen is provided. For example, when the user selects a menu key f1, the electronic device 100 provides an application selection interface for receiving a request for execution of an application.

FIG. 4B illustrates an application selection interface according to a first exemplary embodiment of the present invention.

When the electronic device 100 receives a selection of a menu key, the electronic device 100 provides an application selection interface, as shown in FIG. 4B. The application selection interface may provide at least a part of applications in which the electronic device 100 provides. The user can select and execute a desired application of a phonebook application, a message application, a schedule application, a map application, a memo application, and a television application displayed in the application selection interface.

Hereinafter, for convenience of description, it is assumed that the user requests execution of a phonebook application.

Referring again to FIG. 2, the controller 180 determines whether the electronic device 100 is in a situation corresponding to a sound output mode change reference (S130).

The sound output mode change indicates that the electronic device 100 changes a mode thereof to a speaker output mode while performing communication in a receiver output mode at step S110 and indicates that the electronic device 100 changes a mode thereof to at least one of a receiver output mode and a bone conduction module output mode while performing communication in a speaker output mode at step S110.

Further, a sound output mode change reference is provided to determine whether to perform a control operation for changing a sound output mode when the electronic device 100 receives a request for execution of an application while performing communication.

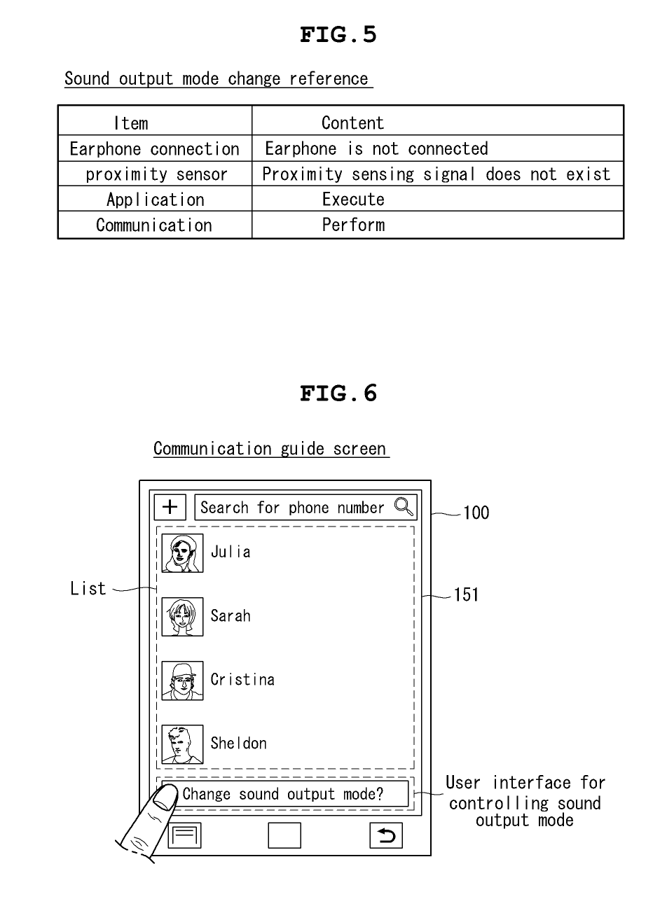

The sound output mode change reference may include at least one reference and will be described in detail with reference to FIG. 5.

FIG. 5 is a table illustrating a sound output mode change reference according to a first exemplary embodiment of the present invention.

Referring to FIG. 5, the sound output mode change reference includes at least one of whether an earphone is connected, whether a proximity sensing signal exists, whether an application is being executed, and whether communication is being performed.

In this case, in a case of at least one of when an earphone is connected, when a proximity sensing signal does not exist, when an application is being executed, and when communication is being performed, it is determined that the electronic device 100 is in a situation corresponding to a sound output mode change reference.

For example, when an earphone is connected or when a proximity sensing signal exists, it is considered that a user's intention trying to enter a speaker output mode is low.

More specifically, when performing communication in a state where an initial sound output mode is a receiver output mode, if an earphone is not connected, a proximity sensing signal does not exist, and an application is being executed, it is determined that the electronic device 100 is in a situation corresponding to a sound output mode change reference.

Alternatively, in a state where communication is performed in a receiver output mode, when an earphone is connected, when a proximity sensing signal exists, and when an application is not being executed, it is determined that the electronic device 100 is not in a situation corresponding to a sound output mode change reference.

If the electronic device 100 is in a situation corresponding to a sound output mode change reference, the process continues at step S140. If the electronic device 100 is not in a situation corresponding to a sound output mode change reference, step S130 is repeated.

That is, the sound output mode change reference provides an effect that effectively uses resources by selectively acquiring a sound output mode change control signal according to step S140 only when the user's intention corresponds to a sound output mode change.

Referring again to FIG. 2, the electronic device 100 acquires a control signal that controls a sound output mode in a state where an execution screen of a requested application is displayed (S140).

As described above, only when it is determined that the electronic device 100 is in a situation corresponding to a sound output mode change reference, the process may continue at step S140, and the process may continue at step S140 without determination whether the electronic device 100 is in a situation corresponding to a sound output mode change reference. Determination whether the electronic device 100 is in a situation corresponding to a sound output mode change reference can be selected according to the user's setting.

The electronic device 100 acquires a control signal for controlling a sound output mode by various methods. The electronic device 100 controls to change a present sound output mode to at least one of a receiver output mode, a speaker output mode, a bone conduction module output mode through the control signal. More specifically, when a present sound output mode is a receiver mode, a mode of the electronic device 100 can be changed to a speaker output mode through a control signal for controlling a sound output mode, and when a present output mode is a speaker mode, a mode of the electronic device 100 can be changed to a receiver output mode through a control signal for controlling a sound output mode.

Hereinafter, for convenience of description, a method of acquiring a control signal for changing a sound output mode to a speaker output mode when a present sound output mode is a receiver output mode will be described. However, this is for convenience of description, and therefore the present invention is not limited to a specific example.

Hereinafter, a method of acquiring a control signal for controlling a sound output mode will be described with reference to FIGS. 6 to 11.

FIG. 6 is a diagram illustrating an example of a method of acquiring a control signal according to a first exemplary embodiment of the present invention.

When describing with reference to FIG. 6, as described above, it is assumed that a present sound output mode is a receiver output mode and a requested application is a phonebook application.

When the electronic device 100 receives a request for execution of a phonebook application, the electronic device 100 outputs a phonebook execution screen through the display 151.

In this case, the electronic device 100 outputs together an execution screen of a requested application and a user interface for controlling a sound output mode through the display 151.

An output of both an execution screen of an application and a user interface for controlling a sound output mode means a simultaneous output of an application execution screen and a user interface.

For example, as shown in FIG. 6, the electronic device 100 may output a user interface for changing a sound output mode in one area of a phonebook execution screen. For another example, the electronic device 100 may reduce a phonebook execution screen to a predetermined size and output the user interface in a newly generated area according to reduction.

The electronic device 100 acquires a control signal for controlling a sound output mode through a user interface for changing the sound output mode.

That is, the electronic device 100 provides together an execution screen of a requested application and a user interface for controlling a sound output mode, and thus the user can determine whether to change a present sound output mode while viewing an application execution screen or to sustain a present sound output mode.

According to a method of acquiring a control signal described with reference to FIG. 6, when the user should check an application while performing communication and change a sound output mode, as needed, the electronic device 100 provides a simpler operating environment.

Hereinafter, another example of a method of acquiring a control signal will be described.

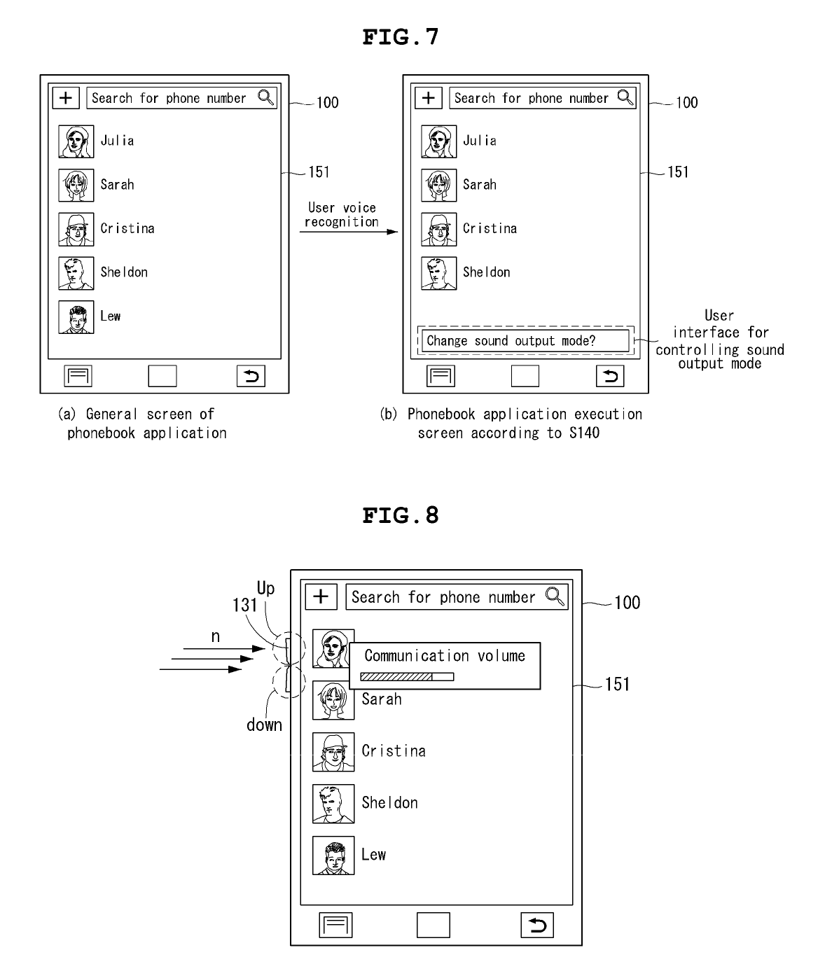

FIG. 7 is a diagram illustrating another example of a method of acquiring a control signal according to a first exemplary embodiment of the present invention.

As described above, it is assumed that a present sound output mode is a receiver output mode and a requested application is a phonebook application.

When the electronic device 100 receives a request for execution of a phonebook application, the electronic device 100 outputs a phone number list, as shown in FIG. 7A.

In this case, when the electronic device 100 recognizes a user voice, the electronic device 100 displays a user interface for changing a sound output mode according to the recognition.

User voice recognition indicates that the electronic device 100 recognizes a user voice of the electronic device 100. That is, when the electronic device 100 acquires a user voice in a state of executing a phonebook application, the electronic device 100 determines that the user's intention is in a speaker output mode rather than a receiver output mode. More specifically, in a state of executing a phonebook application, when a proximity sensing signal does not exist and a user voice of the electronic device 100 is acquired, the electronic device 100 determines that the user's intention is in a speaker output mode rather than a receiver output mode.

For this, the electronic device 100 previously stores information for recognizing the user voice of the electronic device 100 in the memory 160. Thereby, the electronic device 100 determines whether voice fingerprint of a recognized user voice corresponds to that of the user voice stored in the memory 160.

If voice fingerprint of a recognized user voice corresponds to that of the user voice stored in the memory 160, the electronic device 100 outputs a user interface for changing a sound output mode, as shown in FIG. 7B.

Thereby, the electronic device 100 acquires a control signal for changing a sound output mode through the user interface.

According to a method of acquiring a control signal described with reference to FIG. 7, the electronic device 100 more accurately determines whether the user is in an environment to change a sound output mode, and the electronic device 100 provides a user interface for changing a sound output mode based on the determination and thus an effect that can dynamically use a limited display output screen is provided.

Hereinafter, another example of a method of acquiring a control signal for changing a sound output mode will be described.

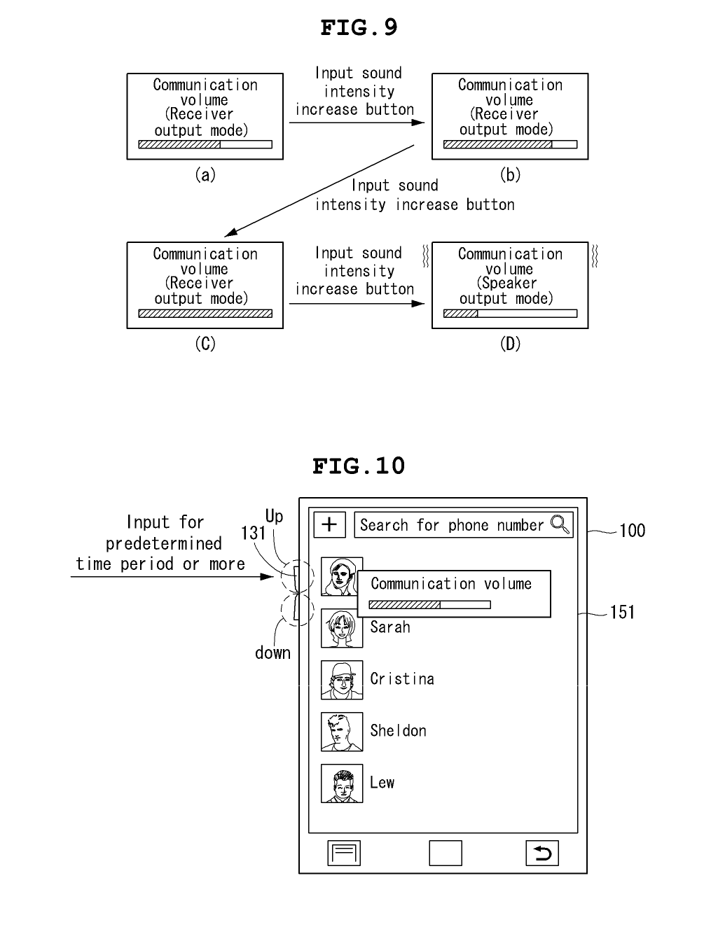

FIGS. 8 and 9 are diagrams illustrating another example of a method of acquiring a control signal according to a first exemplary embodiment of the present invention.

As described above, it is assumed that a present sound output mode is a receiver output mode and a requested application is a phonebook application.

In a state where a phonebook application execution screen is provided, the electronic device 100 receives an input of the volume adjustment button 131.

As an input of the volume adjustment button 131 is received, the electronic device 100 changes a communication volume. For example, when an input of a volume up button is received, the electronic device 100 increases a communication volume and when an input of a volume down button is received, the electronic device 100 decreases a communication volume. In this case, when the electronic device 100 receives a request for a sound level of a predetermined sound level or more through a volume up button, the electronic device 100 can enter to a speaker output mode from a receiver output mode. That is, the electronic device 100 acquires a control signal for changing a sound output mode through the volume adjustment button 131. Here, a predetermined sound level may be, for example, a maximum value of a communication volume.

Referring to FIG. 9, the electronic device 100 performs a receiver output mode in a predetermined sound level, as shown in FIG. 9A. In this case, when the electronic device 100 receives an input of a volume up button by the predetermined number of times, the electronic device 100 increases a communication volume, as shown in FIGS. 9B and 9C. Further, even in a state where a communication volume level is a maximum value, when an input of a volume up button is received, the electronic device 100 changes a sound output mode from a receiver output mode to a speaker output mode, as shown in FIG. 9D.

Alternatively, when the electronic device 100 receives a request for a sound level lower than a predetermined sound level through a volume down button, the electronic device 100 enters to a receiver output mode from a speaker output mode. Here, a predetermined sound level may be, for example, a minimum value of a communication volume.

More specifically, even in a state where a communication volume level is a minimum value, if a volume down button is input, the electronic device 100 changes a sound output mode from a speaker output mode to a receiver output mode.

Thereby, the electronic device 100 acquires a control signal for controlling a sound output mode through the volume adjustment button 131.

According to a method of acquiring a control signal described with reference to FIGS. 8 and 9, the electronic device 100 acquires a control signal for controlling a sound output mode through an existing volume adjustment button 131 for controlling a communication volume and thus a more convenient operating environment is provided.

Hereinafter, another example of a method of acquiring a control signal for controlling a sound output mode will be described.

FIG. 10 is a diagram illustrating another example of a method of acquiring a control signal according to a first exemplary embodiment of the present invention.

As described above, it is assumed that a present sound output mode is a receiver output mode and a requested application is a phonebook application.

In a state where a phonebook application execution screen is provided, when a volume adjustment button 131 is input, if the electronic device 100 receives an input longer than a predetermined time period, the electronic device 100 acquires a control signal for controlling a sound output mode.

For example, when a volume up button is input longer than a predetermined time period, the electronic device 100 acquires a control signal for changing the sound output mode from a receiver output mode to a speaker output mode.

Alternatively, if a volume down button is input longer than a predetermined time period, the electronic device 100 acquires a control signal for changing the sound output mode from a speaker output mode to a receiver output mode.

Even with a method of acquiring a control signal described with reference to FIG. 10, the electronic device 100 acquires a control signal for controlling a sound output mode through an existing volume adjustment button 131 for controlling a communication volume and thus a more convenient operating environment is provided.

Hereinafter, another example of a method of acquiring a control signal for controlling a sound output mode will be described.

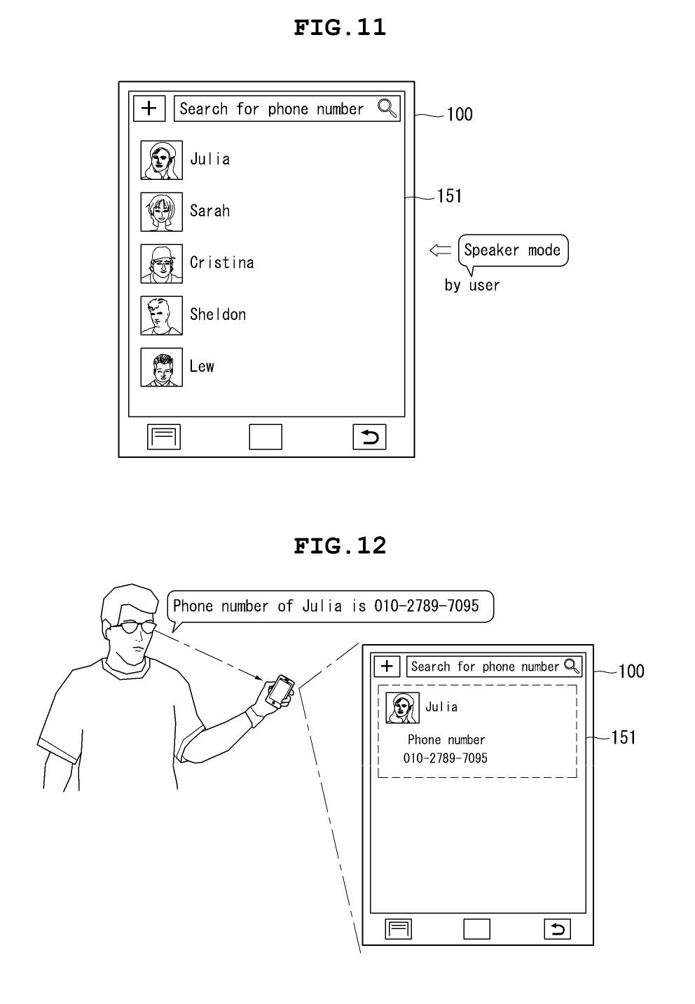

FIG. 11 is a diagram illustrating another example of a method of acquiring a control signal according to a first exemplary embodiment of the present invention.

As described above, it is assumed that a present sound output mode is a receiver output mode and a requested application is a phonebook application.

In a state where a phonebook application execution screen is output, when a specific voice instruction is received, the electronic device 100 acquires a control signal for changing a sound output mode based on the voice instruction.

For example, as shown in FIG. 10, when the electronic device 100 receives an input of a voice instruction, for example, a “speaker output mode” corresponding to a sound output mode change, the electronic device 100 acquires a control signal for changing a sound output mode from a receiver output mode to a speaker output mode.

Alternatively, although not shown, when the electronic device 100 receives an input of a voice instruction, for example, a “receiver output mode”corresponding to a sound output mode change, the electronic device 100 acquires a control signal for changing a sound output mode from a speaker output mode to a receiver output mode.

The specific voice instruction is an example, and thus the electronic device 100 can acquire a control signal for controlling a sound output mode change through another voice instruction.

According to a method of acquiring a control signal described with reference to FIG. 11, because the electronic device 100 can acquire a control signal for controlling a sound output mode without using display resources, the electronic device 100 outputs an execution screen of an executing application without disturbing.

In the foregoing description, a method of acquiring a control signal for changing a sound output mode according to an exemplary embodiment of the present invention has been described with reference to FIGS. 6 to 11.

Referring again to FIG. 2, the electronic device 100 controls a sound output mode according to the control signal (S150).

That is, the electronic device 100 changes a sound output mode from a receiver output mode to a speaker output mode and from a speaker output mode to a receiver output mode according to the control signal.

Accordingly, when a sound output mode is changed from a receiver output mode to a speaker output mode, as shown in FIG. 12, the user can continue to communicate with another party while viewing an application execution screen, and the electronic device 100 provides a more convenient communication environment.

According to a method of operating an electronic device according to the first exemplary embodiment, the electronic device 100 provides an environment that can easily change a sound output mode even in a state where a specific application is displayed while performing communication.

Hereinafter, a method of operating an electronic device according to a second exemplary embodiment of the present invention will be described.

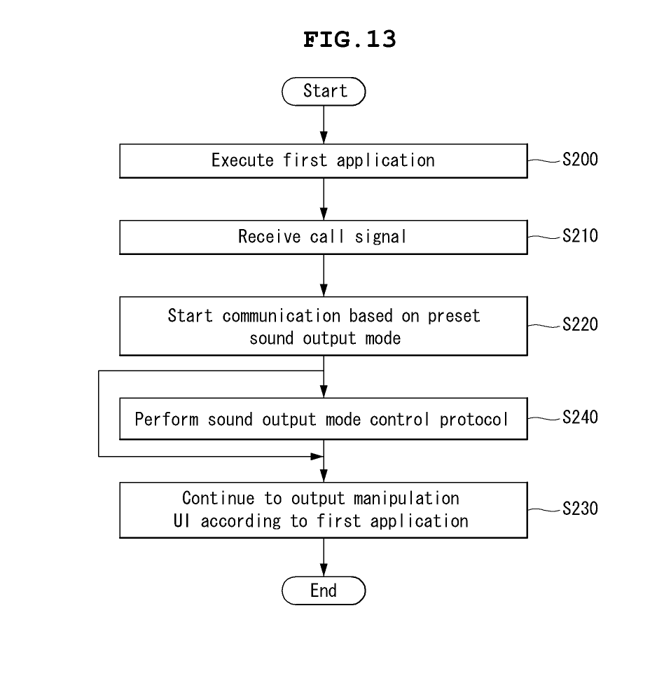

FIG. 13 is a flowchart illustrating a method of operating an electronic device according to a second exemplary embodiment of the present invention.

In a method of operating an electronic device according to a second exemplary embodiment of the present invention, when the first application execution screen is provided, if communication is started, the first application execution screen is continuously output.

For this, a method of operating an electronic device according to a second exemplary embodiment of the present invention includes at least one of step of executing the first application (S200), step of receiving a call signal (S210), step of starting communication based on a preset sound output mode (S220), and step of continuing to output a manipulation interface according to the first application (S230).

In this case, a method of operating an electronic device according to a second exemplary embodiment may be performed in combination with a method of operating an electronic device according to the above-described first exemplary embodiment. That is, a method of operating an electronic device according to a second exemplary embodiment of the present invention may further include step of performing a sound output mode control protocol (S240) according to a first exemplary embodiment. Hereinafter, each step will be described in detail.

The electronic device 100 executes the first application (S200).

The electronic device 100 receives a request for execution of the first application by various methods, and this has been described with reference to the first exemplary embodiment. Hereinafter, it is assumed that the first application is a television control application. This is for convenience of description and the present invention is not limited to a specific application.

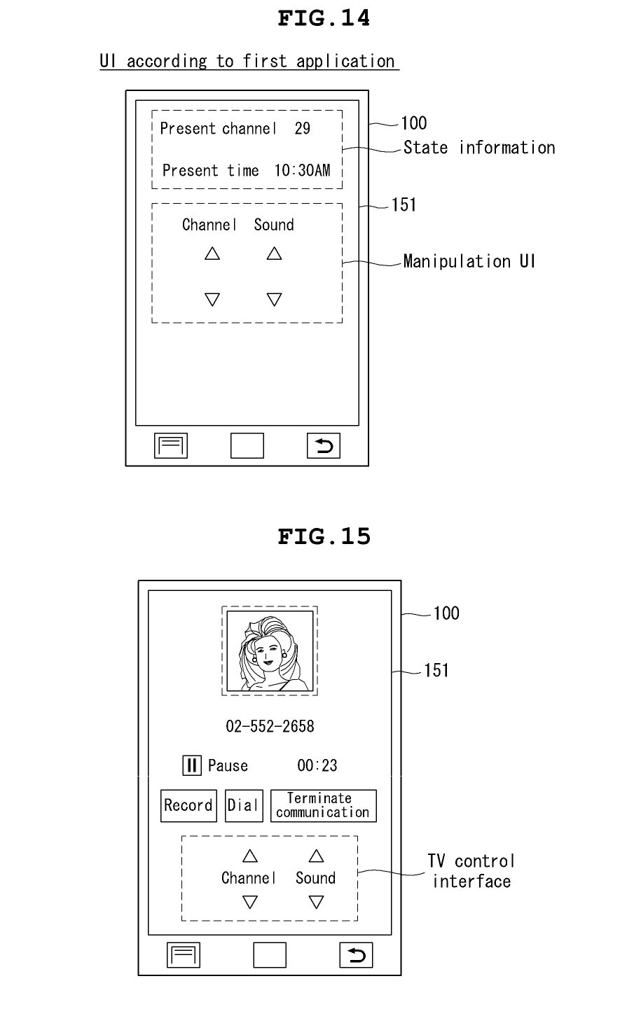

As a television control application is requested, the electronic device 100 outputs an interface for controlling a television, as shown in FIG. 14.

FIG. 14 is a diagram illustrating an interface for controlling a television according to a second exemplary embodiment of the present invention.

Referring to FIG. 14, an interface for controlling a television includes state information including a present channel and a present time and a manipulation area that can control a channel and sound.

Accordingly, the user can control a television through a television control interface.

The electronic device 100 receives a call signal while outputting a television control interface (S210).

As the electronic device 100 receives a call signal, the electronic device 100 starts communication. In this case, the electronic device 100 outputs communication sound according to a preset sound output mode (S220).

The electronic device 100 continues to output a manipulation interface according to the first application (S230).

That is, the electronic device 100 provides an environment in which the user can continuously use a manipulation interface according to the first application even while performing communication.

The electronic device 100 continues to output a manipulation interface according to the first application even while performing communication by various methods. For example, referring to FIG. 15, the electronic device 100 may output a manipulation interface on a guide screen related to communication. Further, when the electronic device 100 outputs a manipulation interface on a communication related guide screen, the manipulation interface may be appropriately changed. This is considered that when the electronic device 100 outputs only a television control interface, space of the display 151 can be entirely used, but when the electronic device 100 outputs a communication related guide screen, space use of the display 151 is partially limited by the communication related guide screen. Therefore, the electronic device 100 selects a manipulating area of a television control interface and outputs the manipulating area on the communication related guide screen, thereby maximizing space use of the display 151.

The user can receive a control interface together with a communication related guide screen, i.e., various information.

Further, a method of operating an electronic device according to a second exemplary embodiment of the present invention can be performed in combination with a method of operating an electronic device according to the first exemplary embodiment.

For this, the electronic device 100 performs a sound output mode control protocol according to the first exemplary embodiment after step S220 (S240). As described above, the sound output mode control protocol according to the first exemplary embodiment includes at least one of step of determining whether a request for execution of a second application exists, determining whether corresponding to a sound output mode change reference, step of acquiring a control signal for controlling a sound output mode in a state where a requested application is displayed, and step of controlling a sound output mode according to a control signal.

That is, when the first application is executed at step S200 and the second application is executed at step S240, while continuing to output a manipulation interface according to the first application, the electronic device 100 acquires a control signal for a sound output mode change.

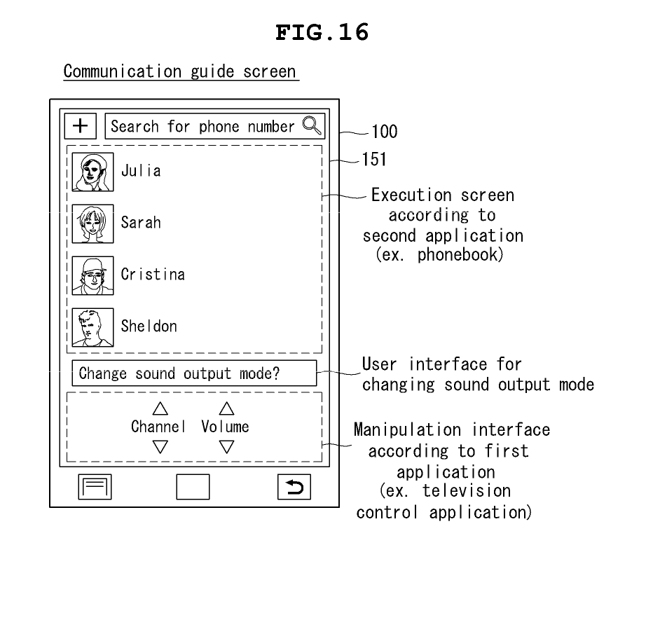

FIG. 16 is a diagram illustrating an interface according to a second exemplary embodiment of the present invention.

Referring to FIG. 16, it is assumed that a television control application is requested as the first application, and a phonebook application is requested as a second application.

Thereby, the electronic device 100 continues to output a manipulation interface according to a television control application even while performing communication and continues to output a manipulation interface according to a television control application even when a phonebook application is requested after communication is started.

Further, the electronic device 100 outputs an interface for a sound output mode change together with the manipulation interface according to a television control application.

Therefore, the electronic device 100 provides complex information and various interface operating environments to the user, thereby providing user convenience.

In the foregoing description, a method of operating an electronic device according to a second exemplary embodiment of the present invention has been described.

Hereinafter, a method of operating an electronic device according to a third exemplary embodiment of the present invention will be described.

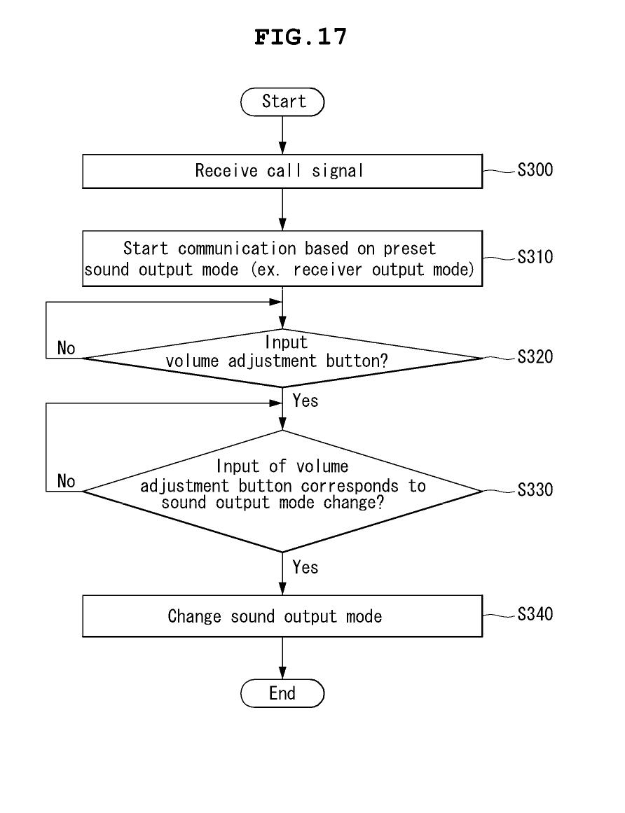

FIG. 17 is a flowchart illustrating a method of operating an electronic device according to a third exemplary embodiment of the present invention.

The method of operating an electronic device according to a third exemplary embodiment of the present invention provides a method of controlling a sound output mode through a volume adjustment button while performing communication.

For this, the method of operating an electronic device according to a third exemplary embodiment of the present invention includes at least one of step of receiving a call signal (S300), step of starting communication based on a preset sound output mode (S310), step of determining whether an input of a volume adjustment button is received (S320), step of determining whether the input of the volume adjustment button corresponds to a sound output mode change (S330), and step of changing a sound output mode (S340).

Hereinafter, each step will be described in detail. When describing the third exemplary embodiment of the present invention, constituent elements identical to or corresponding to those of the previously described first exemplary embodiment will be omitted.

When a call signal is received (S300), the electronic device 100 starts communication based on a preset sound output mode (S310). This is equal to a description in the first exemplary embodiment and a description thereof will be omitted. Hereinafter, it is assumed that a preset sound output mode is a receiver output mode.

The electronic device 100 determines whether a volume adjustment button is input (S320).

That is, the electronic device 100 determines whether the volume adjustment button 131 is input while performing communication. If a volume adjustment button is not input, step S320 is repeated. If a volume adjustment button is input, step S330 is performed.

The electronic device 100 determines whether the input of a volume adjustment button corresponds to a sound output mode change (S330).

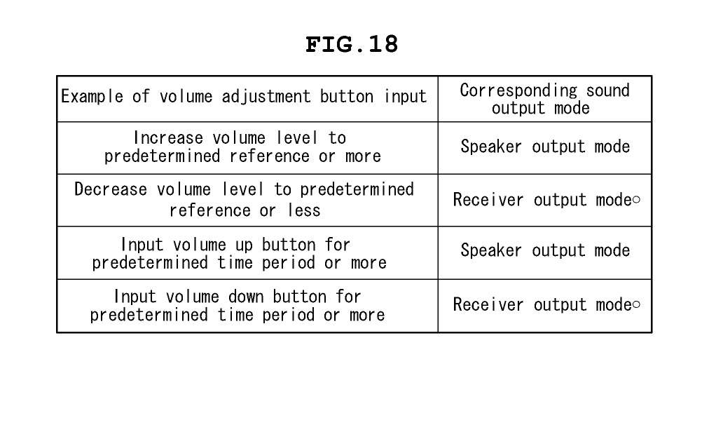

The electronic device 100 determines whether a corresponding input is a request for a sound output mode change through the input of a volume adjustment button. A method in which the electronic device 100 determines whether the input of a volume adjustment button corresponds to a sound output mode change will be described with reference to FIG. 18.

FIG. 18 is a table illustrating a volume adjustment button input and a sound output mode corresponding thereto according to a third exemplary embodiment of the present invention.

Referring to FIG. 18, an input of increasing a volume level to a predetermined reference or more corresponds to a speaker output mode, and an input of lowering a volume level to a predetermined reference or less corresponds to a receiver output mode. In this case, an input of increasing a volume level to a predetermined reference or more is an input of additionally increasing a volume level in a state where, for example, a volume level is a maximum value. Further, an input of lowering a volume level to a predetermined reference or less is an input of additionally reducing a volume level in a state where, for example, a volume level is a minimum value.

Referring to FIG. 18, an input of a volume up button for a predetermined time period or more corresponds to a speaker output mode, and an input of a volume down button for a predetermined time period or more corresponds to a receiver output mode.

Accordingly, the electronic device 100 determines a sound output mode corresponding to a corresponding volume adjustment button input.

Referring again to FIG. 17, the electronic device 100 changes a sound output mode (S340).

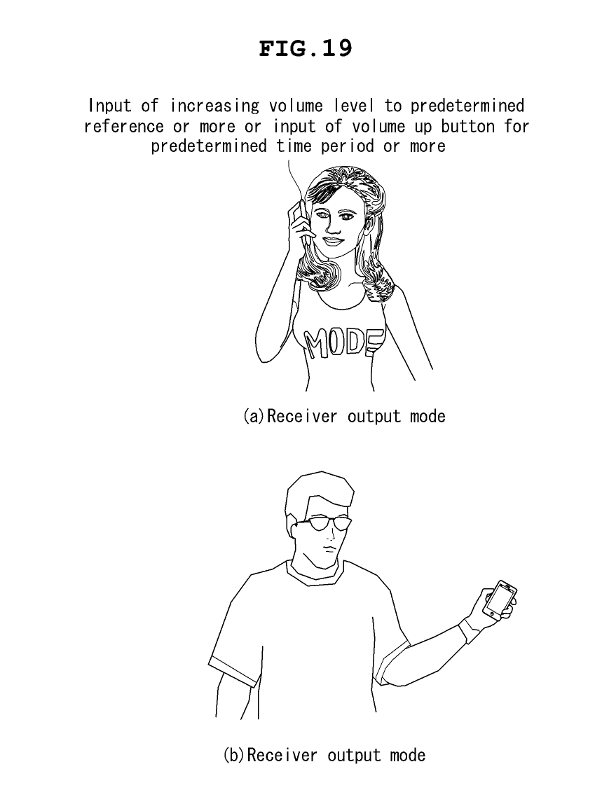

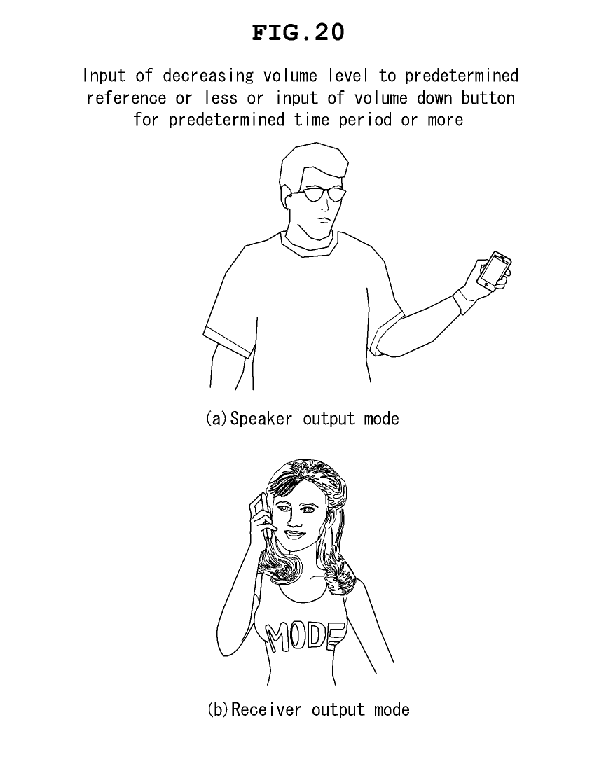

That is, the electronic device 100 changes a present sound output mode to a sound output mode corresponding to a corresponding volume adjustment button input. A specific application example of step S340 will be described with reference to FIGS. 19 and 20.

FIGS. 19 and 20 are diagrams illustrating a use state of step S340 according to a third exemplary embodiment of the present invention.

Referring to FIG. 19, when the electronic device 100 receives an input of increasing a volume level to a predetermined reference value or more through the volume adjustment button 131, or when the electronic device 100 receives an input of the volume up button for a predetermined time period or more, the electronic device 100 changes and outputs a present receiver output mode to a speaker output mode.

Further, referring to FIG. 20, when the electronic device 100 receives an input of reducing a volume level to a predetermined reference value or less through the volume adjustment button 131, or when the electronic device 100 receives an input of the volume down button for a predetermined time period or more, the electronic device 100 changes a present receiver output mode to a speaker output mode change.

According to the third exemplary embodiment of the present invention, a sound output mode can be easily controlled through the volume adjustment button. That is, as the user simply manipulates a volume adjustment button, a sound output mode can be changed while performing communication and thus a more convenient operating environment can be provided.

Various exemplary embodiments disclosed in this document can be executed individually or in combination. Further, steps constituting each exemplary embodiment can be executed in combination of steps constituting other exemplary embodiments. This means that the first to third exemplary embodiments of the present invention can be executed in combination.

Further, when describing the first to third exemplary embodiments of the present invention, a case of changing from a receiver output mode to a speaker output mode is described, but this is for convenience of description, and a control of changing from a speaker output mode to a receiver output mode can be performed according to the first to third exemplary embodiments of the present invention.

Further, when describing the first to third exemplary embodiment of the present invention, a change between a receiver output mode and a speaker output mode is described, but the first to third exemplary embodiments of the present invention are not a change between a receiver output mode and a speaker output mode and can be applied to another output mode, for example, a bone conduction module output mode. Further, a sound output mode according to an exemplary embodiment of the present invention can include other sound output modes in addition to the receiver output mode, the speaker output mode, and the bone conduction module output mode.

Various exemplary embodiments of the present invention can be embodied by computer readable media. The media may include a single or a combination of, for example, a program code, a data file, and a data structure for embodying an exemplary embodiment of the present invention. An example of such media may include media structured to store and execute a program, such as magnetic media, optical recording media such as a CD and a DVD, a ROM, a RAM, and a flash memory. An example of a program code may include a high-level language code that can be executed by a computer using an interpreter as well as a machine language code manufactured by a compiler.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### DESCRIPTION OF REFERENCE NUMERALS

100: electronic device
110: wireless communication unit
120: A/V input unit
130: user input unit
140: sensing unit
141: proximity sensor
150: output unit
151: display
152: audio output module
152a: receiver
152b: speaker
152c: bone conduction module
160: memory
170: interface unit
180: controller
181: multimedia module
190: power supply unit

What is claimed is:

1. An electronic device comprising:
a display;
an audio output unit; and
a controller configured to:
detect a request for execution of a first application while outputting sound in a particular sound output mode through the audio output unit,
control display, on the display, of an execution screen of the requested first application based on detecting the request for execution of the first application,
identify that the audio output unit is outputting sound in the particular sound output mode at a time associated with the request for execution of the first application,
determine whether to perform an operation directed to controlling the particular sound output mode based on the identification that the audio output unit is outputting sound in the particular sound output mode and the request for execution of the first application; and
based on a determination to perform the operation directed to controlling the particular sound output mode, perform the operation directed to controlling the particular sound output mode in a state of displaying the execution screen of the requested first application.

2. The electronic device of claim 1, wherein the audio output unit comprises at least one of a receiver, a speaker, and a bone conduction module.

3. The electronic device of claim 1, wherein the sound output mode comprises at least one of a receiver output mode, a speaker output mode, and a bone conduction module output mode.

4. The electronic device of claim 1, wherein the controller is configured to:
identify that the audio output unit is outputting sound in a receiver output mode at a time associated with the request for execution of the first application,
determine whether to perform an operation directed to changing the receiver output mode to a speaker output mode based on the identification that the audio output unit is outputting sound in the receiver output mode and the request for execution of the first application, and
based on a determination to perform the operation directed to changing the receiver output mode to the speaker output mode, perform the operation directed to changing the receiver output mode to the speaker output mode in a state of displaying the execution screen of the requested first application.

5. The electronic device of claim 1, wherein the controller is configured to:
identify that the audio output unit is outputting sound in a speaker output mode at a time associated with the request for execution of the first application,
determine whether to perform an operation directed to changing the speaker output mode to a receiver output mode based on the identification that the audio output unit is outputting sound in the speaker output mode and the request for execution of the first application, and
based on a determination to perform the operation directed to changing the speaker output mode to the receiver output mode, perform the operation directed to changing the speaker output mode to the receiver output mode in a state of displaying the execution screen of the requested first application.

6. The electronic device of claim 1, wherein the controller is configured to:
detect a criterion associated with the electronic device;
access a sound output mode change rule;
compare the detected criterion to the accessed sound output mode change rule;
based on comparison results, determine whether or not the sound output mode change rule is satisfied; and
based on a determination that the sound output mode change rule is satisfied, determine to perform the operation directed to controlling the particular sound output mode.

7. The electronic device of claim 6, wherein the controller is configured to:
detect the criterion associated with the electronic device by:
detecting whether or not an earphone is connected to the electronic device,
detecting whether or not a proximity sensing signal exists,
detecting whether communication for outputting sound is being performed, and
detecting whether the execution screen related to the first application is being displayed, and
determine to perform the operation directed to controlling the particular sound output mode based on:
detecting that an earphone is not connected to the electronic device,
detecting that a proximity sensing signal does not exist,
detecting that communication for outputting sound is being performed, and
detecting that the execution screen related to the first application is being displayed.

8. The electronic device of claim 1, wherein the controller is configured to perform the operation directed to controlling the particular sound output mode by controlling display, on the display, of a user interface for controlling the particular sound output mode together with the execution screen.

9. The electronic device of claim 1, wherein the controller is configured to:
recognize that audio input is being provided to the electronic device,
determine to perform the operation directed to controlling the particular sound output mode based on the recognition that audio input is being provided to the electronic device, and
perform the operation directed to controlling the particular sound output mode by controlling display, on the display, of a user interface for controlling the particular sound output mode together with the execution screen of the first application.

10. The electronic device of claim 1, wherein the controller is configured to:
receive a voice instruction corresponding to a sound output mode change, and
determine to perform the operation directed to controlling the particular sound output mode based on the received voice instruction.

11. The electronic device of claim 1, wherein the controller is configured to, when a second application is being executed before a start of a communication that results in the sound being output, control display of an execution screen of the second application together with the execution screen of the first application.

12. An electronic device comprising:
a display; and
a controller configured to:
detect a start of a communication;
determine that the display is displaying an application execution screen at a time associated with the start of the communication; and
based on the start of the communication and the determination that the display is displaying an application execution screen at the time associated with the start of the communication, control display of the application execution screen together with a guide screen related to the communication.

13. An electronic device comprising:
an audio output unit;
a communication sound adjustment button that is configured to raise or lower a sound level of the audio output unit throughout a range of at least four sound levels; and
a controller configured to:
perform communication based on a particular sound output mode;
obtain, through the communication sound adjustment button and while performing communication based on the particular sound output mode, a control signal for controlling the particular sound output mode; and
perform an operation directed to controlling the particular communication sound output mode based on the control signal.

14. The electronic device of claim 13, wherein the controller is configured to:
obtain, through the communication sound adjustment button, input that increases the sound level of the audio output unit;
compare the increased sound level of the audio output unit to a predetermined sound level;
based on comparison results, determine whether the increased sound level of the audio output unit meets the predetermined sound level; and
change the particular sound output mode to a speaker output mode based on a determination that the increased sound level of the audio output unit meets the predetermined sound level.

15. The electronic device of claim 14, wherein the predetermined sound level is a maximum sound level.

16. The electronic device of claim 13, wherein the controller is configured to:
obtain, through the communication sound adjustment button, input that decreases the sound level of the audio output unit;
compare the decreased sound level of the audio output unit to a predetermined sound level;
based on comparison results, determine whether the decreased sound level of the audio output unit meets the predetermined sound level; and
change the particular sound output mode to a receiver output mode based on a determination that the decreased sound level of the audio output unit meets the predetermined sound level.

17. The electronic device of claim 16, wherein the predetermined sound level is a minimum sound level.

18. The electronic device of claim 13, wherein the communication sound adjustment button comprises a communication sound increase button and a communication sound decrease button,
wherein the controller is configured to:
obtain, through the communication sound increase button, input held at the communication sound increase button;
determine whether the input has been held at the communication sound increase button for at least a predetermined time period; and
based on a determination that the input has been held at the communication sound increase button for at least the predetermined time period, change the particular sound output mode to a speaker output mode.

19. The electronic device of claim 13, wherein the communication sound adjustment button comprises a communication sound increase button and a communication sound decrease button,
wherein the controller is configured to:
obtain, through the communication sound decrease button, input held at the communication sound decrease button;
determine whether the input has been held at the communication sound decrease button for at least a predetermined time period; and
based on a determination that the input has been held at the communication sound decrease button for at least the predetermined time period, change the particular sound output mode to a receiver output mode.

20. A method of operating an electronic device, the method comprising:
outputting, through an audio output unit, sound in a particular sound output mode;
receiving a request for execution of a first application while outputting sound in the particular sound output mode;
controlling display, on a display, of an execution screen of the requested first application based on receiving the request for execution of the first application;
identifying that the audio output unit is outputting sound in the particular sound output mode at a time associated with the request for execution of the first application;
determining whether to perform an operation directed to controlling the particular sound output mode based on the identification that the audio output unit is outputting sound in the particular sound output mode and the request for execution of the first application; and
based on a determination to perform the operation directed to controlling the particular sound output mode, performing the operation directed to controlling the particular sound output mode in a state of displaying the execution screen of the requested first application.

21. The method of claim 20, wherein the sound output mode comprises at least one of a receiver output mode, a speaker output mode, and a bone conduction module output mode.

22. The method of claim 20, wherein determining whether to perform an operation directed to controlling the particular sound output mode comprises:
detecting a criterion associated with the electronic device;
accessing a sound output mode change rule;
comparing the detected criterion to the accessed sound output mode change rule;
based on comparison results, determining whether or not the sound output mode change rule is satisfied;
based on a determination that the sound output mode change rule is satisfied, determining to perform the operation directed to controlling the particular sound output mode.

23. The method of claim 20, further comprising:
controlling display, on the display, of an execution screen of a second application before a start of a communication that results in the sound being output, and
based on the start of the communication, controlling display, on the display, of the execution screen of the second application together with the execution screen of the first application.
